(19) United States
(12) Patent Application Publication
(10) Pub. No.: US 2006/0284663 A1
(43) Pub. Date: Dec. 21, 2006

(54) TIMING CONTROL CIRCUIT AND METHOD

(76) Inventors: Chien-Hung Lu, Taipei County (TW); Yi-Chiang Lai, Taoyuan County (TW); Ho-Ming Su, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/160,232

(22) Filed: Jun. 15, 2005

(51) Int. Cl. H03H 11/26

(52) U.S. Cl. 327/268

(57) ABSTRACT

A timing control circuit and a timing control method are provided. The circuit and method is for outputting a plurality of latch pulses in a TFT-LCD to avoid a rewriting phenomenon. The timing control circuit is characterized in that among the latch pulses, except for the first latch pulse, each latch pulse synchronizes with or follows behind a previous latch pulse corresponding thereto, and at least one latch pulse falls behind a previous latch pulse corresponding thereto.

### BACKGROUND OF THE INVENTION

1. Field of the Invention

The present invention relates to a timing control circuit and a timing control method, and more particularly to a timing control circuit applied to a thin film transistor liquid crystal display (TFT LCD) and a timing control method.

2. Description of the Related Art

FIG. 1 is a drawing showing a traditional TFT LCD panel 100 and a related driving signal sequence. Referring to FIG. 1, the TFT LCD panel 100 comprises eight source drivers SD1-SD8 and three gate drivers GD1-GD3. Whenever a latch pulse LP is in the falling edge, the source drivers SD1-SD8 output pixel signals S-Line required for displaying. The gate drivers GD1-GD3 also output the gate pulses so that the pixel signals S-Line enter the corresponding gate lines. Referring to FIG. 1, G1 represents the gate pulse of the first gate line, corresponding to the Data_G1 of the pixel signal S-Line, or the waveform of the first gate line. G2 represents the gate pulse signal of the second gate line, corresponding to Data_G2 of the pixel signal S-Line, or the waveform of the second gate line.

The disadvantage of the conventional technology is the rewrite issue. For example, in the TFT LCD panel 100 shown in FIG. 1, the rewriting would easily occur at the area 101, because during the transmission of the gate pulses G1 and G2 from the left to the right of the TFT LCD panel 100, they are affected by the resistors and capacitors of the circuit, such that thin film transistors on the same gate line are not turned on simultaneously. Under the situation that a same gate pulse is applied to a same gate line, the thin film transistors away from the input terminal of the gate line, i.e., the right of the TFT LCD panel 100, are the last ones to be turned on/off.

Since the source drivers SD1-SD8 receive the same latch pulse LP, and output pixel signals S-Line simultaneously. That is, pixels on the same gate line will receive the pixel signals S-Line simultaneously. As a result, rewriting would occur, such as A1 of the pixel signal S-Line. Due to the delay of the gate pulse G1 received by the pixel at the right of the first gate line, which is shown in the dotted line, the pixel is not turned off yet. The data Data_G2 of the second gate line has appeared in the pixel signal S-Line. That is, the data Data_G1 and Data_G2 are written in the pixel on the right of the gate line. Thus rewriting occurs.

To avoid the uneven brightness on the scan lines due to rewriting, two methods have been proposed. FIG. 2 is a drawing showing a driving signal sequence of avoiding the rewriting of the conventional technology. Referring to FIG. 2, the gate turn-off signal OE is used to turn off the pixel in advance, as shown in A2. Even if there is transmission delay, rewriting would not occur. The disadvantage of using the gate turn-off signal OE is that by turning off the pixel in advance, the charging time of the pixel must be sacrificed. For a high-resolution or large-sized TFT LCD panel, insufficient charging may be another issue.

The second method of avoiding rewriting is to provide the vertical clock (not shown) in advance to turn off the pixel ahead of time. Like the first method described above, the disadvantage of the second method is the insufficient charging from turning off the pixel early.

Accordingly, a better way is desired to avoid both the insufficient charging and rewriting issues.

### SUMMARY OF THE INVENTION

Accordingly, the present invention is directed to a timing control circuit to overcome the disadvantages of the conventional technology and solve the rewriting issue and the insufficient charging problem. The advantages of the present invention include increasing the charging time for pixels, reducing the size of thin film transistors, and increasing aperture ratio.

The present invention is also directed to a time sequence control method to overcome the disadvantages of the conventional technology and solve the rewriting issue and the insufficient charging problem. The advantages of the present invention include increasing the charging time for pixels, and reducing electrical field interference resulting from different output timing of source drivers.

To achieve the objects described above and other objects, the present invention provides a timing control circuit for outputting a plurality of latch pulses. The timing control circuit is characterized in that among the latch pulses, except for the first latch pulse, each latch pulse synchronizes with or follows behind a previous latch pulse, and at least one latch pulse falls behind a previous latch pulse.

According to an embodiment of the timing control circuit described above, there are two latch pulses, and the second latch pulse is behind the first latch pulse.

According to an embodiment of the timing control circuit described above, the timing control circuit further comprises a timing controller and a delay apparatus. The timing controller outputs the first latch pulse. The delay apparatus receives and delays the first latch pulse to generate and output the second latch pulse.

According to an embodiment of the timing control circuit described above, the delay apparatus further comprises a resistor, a capacitor, and a buffer. The resistor is coupled to an input terminal of the delay apparatus. The capacitor is coupled between the resistor and a ground line. The buffer is coupled among the resistor, the capacitor and an output terminal of the delay apparatus, receiving a signal from a connection point of the resistor and the capacitor, processes the signal into a square wave and outputs the square wave.

According to an embodiment of the timing control circuit described above, except the first latch pulse, each latch pulse falls behind the previous latch pulse corresponding thereto.

According to an embodiment of the timing control circuit described above, the timing control circuit further comprises a timing controller and a delay circuit. The timing controller outputs the first latch pulse. The delay circuit, according to the first latch pulse, generates and outputs the other latch pulses.

According to an embodiment of the timing control circuit described above, the timing control circuit further comprises a plurality of delay apparatuses. The number of the delay apparatus is the number of the latch pulses minus 1. Wherein, the first delay apparatus is coupled to the timing controller, and the I-th delay apparatus is coupled to the (I−1)-th delay apparatus. The I-th delay apparatus receives and delays the I-th latch pulse to generate and output the (I+1)-th latch pulse. Wherein, I is an positive integer, 1≦I≦N−1, and N is the amount of the latch pulses.

The present invention also provides a timing control method, wherein a plurality of latch pulses are provided. The timing control method is characterized in that among the latch pulses, except for the first latch pulse, each latch pulse synchronizes with or follows behind a previous latch pulse corresponding thereto, and at least one latch pulse falls behind a previous latch pulse corresponding thereto.

In the present invention, signal delays are provided to the latch pulses from different source drivers. In cooperation with the transmission delay of the gate pulse, the area with obvious gate pulse delays receives the corresponding pixel signals later. With the cooperation of the delays of the gate pulse and the pixel signal, rewriting can be effectively prevented. Unlike the conventional technology in which pixels are turned off in advance, the present invention can increase pixel charging time to reduce the size of the thin film transistors and increase aperture ratio. In addition, because source drivers have different output timing, electrical field interference can be reduced.

The above and other features of the present invention will be better understood from the following detailed description of the preferred embodiments of the invention that is provided in communication with the accompanying drawings.

### BRIEF DESCRIPTION OF THE DRAWINGS

FIG. 1 is a drawing showing a rewriting phenomenon in a traditional TFT LCD panel.

FIG. 2 is a drawing showing a driving signal sequence when solving the rewriting phenomenon of the conventional technology.

FIG. 3 is a drawing showing a driving signal sequence of a timing control circuit according to an embodiment of the present invention.

FIG. 4 is a schematic drawing showing a timing control circuit according to another embodiment of the present invention.

FIG. 5 is a schematic drawing showing a timing control circuit according to another embodiment of the present invention.

FIG. 6 is a schematic drawing showing a timing control circuit according to another embodiment of the present invention.

FIG. 7 is a schematic drawing showing a delay apparatus in a timing control circuit according to an embodiment of the present invention.

FIG. 8 is a drawing showing a signal sequence of the delay apparatus shown in FIG. 7.

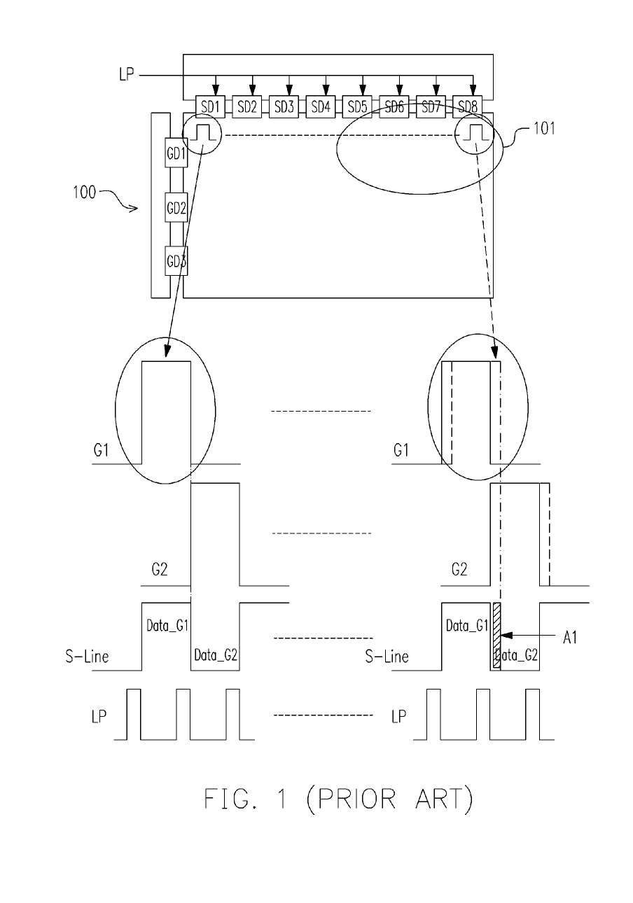

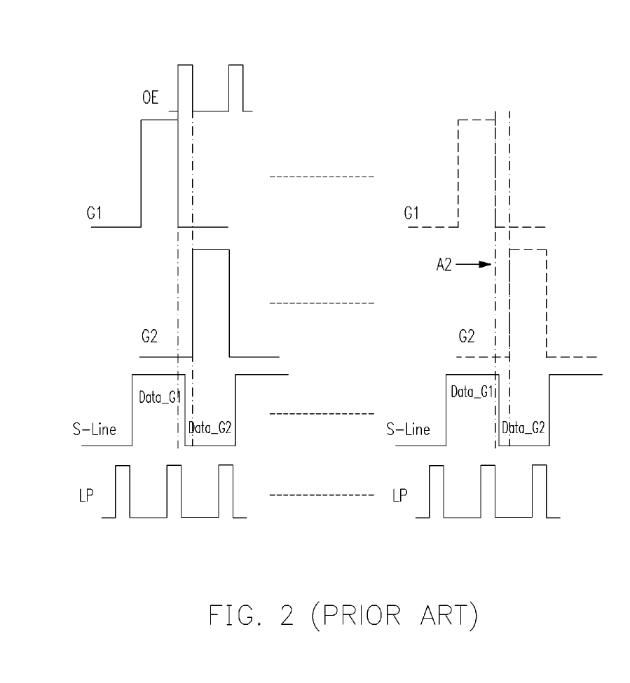

### DESCRIPTION OF SOME EMBODIMENTS

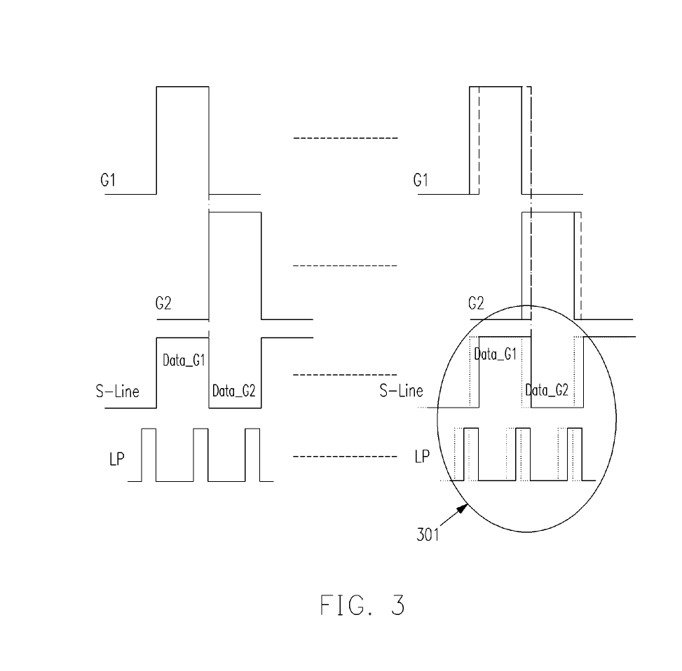

In the present invention, signal delays are added in the latch pulses in cooperation with the transmission delay of the gate pulses. The source driver outputs the pixel signal at the falling edge of the received latch pulse. After the latch pulse is delayed, the output of the pixel signal from the source driver is also delayed. FIG. 3 is a drawing showing a driving signal sequence of a timing control circuit according to an embodiment of the present invention. Referring to FIG. 3, at the right side of the time sequence, the delayed gate pulses G1 and G2 are represented by dotted lines. The delayed latch pulse LP and the affected pixel signal S-Line are represented by solid lines. After delay, all signals are synchronized, and rewriting does not occur.

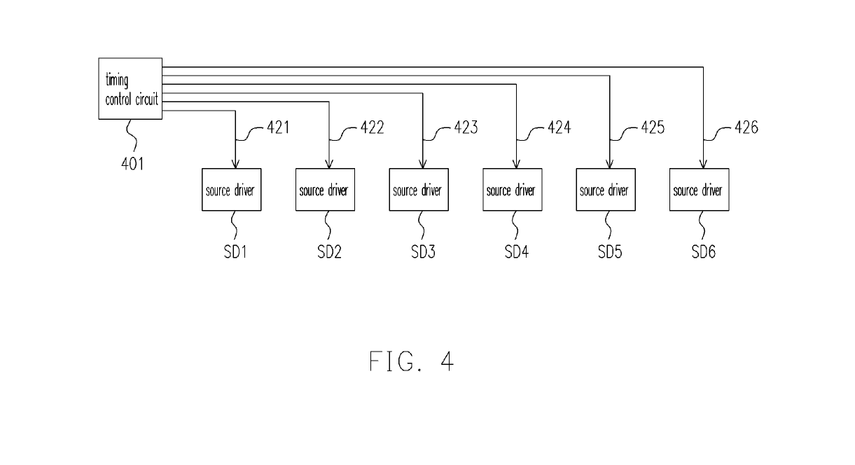

FIG. 4 is a schematic drawing showing a timing control circuit according to an embodiment of the present invention. Referring to FIG. 4, the timing control circuit 401 and the output latch pulses 421-426 are shown. In FIG. 4, six source drivers SD1-SD6 receive the latch pulses 421-426, respectively. In this embodiment, except for the first latch pulse 421, each of the latch pulses 422-426 synchronize with the previous latch pulses 421-425 corresponding thereto, i.e., without delay. Each of the latch pulses 422-426 may follow behind the previous latch pulses 421-425 corresponding thereto, i.e. with delay. The delay time between two of the latch pulses 421-426 can be the same or not. As long as the delay time of two of the latch pulses 421-426 works with the increasing delay of the gate pulses during transmission, the rewriting issue would not occur to all pixels on the same gate line. Accordingly, among the latch pulses 421-426, at least one of the latch pulses 422-426 is behind the previous latch pulse 421-425 corresponding thereto.

There are many ways to add the signal delay in the latch pulses. For example, a delay apparatus can be used between two latch pulses which need to be delayed. In another method, an original latch pulse can be delayed for different times to generate different latch pulses. Other similar methods may also be used, which are all in the scope of the present invention.

Referring to FIG. 4, there are six latch pulses 421-426 corresponding to the source drivers SD1-SD6, respectively. The present invention, however, is not limited to the embodiment of FIG. 4. In other embodiments, a latch pulse may correspond to one or more source drivers, and vice versa, as shown in the following embodiment. The amounts of the latch pulses and the source drivers can be any number larger than 1.

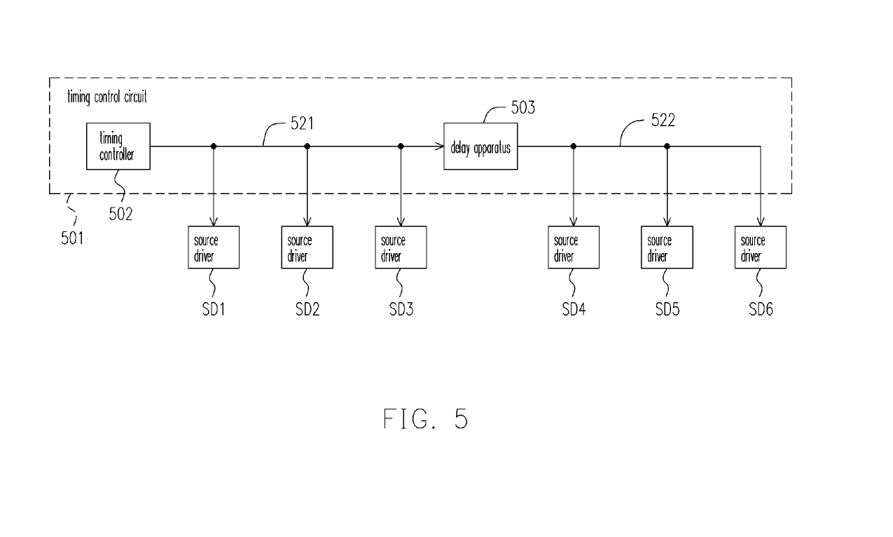

FIG. 5 is a schematic drawing showing a timing control circuit according to another embodiment of the present invention. The timing control circuit 501 only provides two latch pulses 521 and 522. The timing control circuit 501 comprises the timing controller 502 and the delay apparatus 503. Wherein, the timing controller 502 provides the latch pulse 521 to the source drivers SD1-SD3. The delay apparatus 503 receives and delays the latch pulse 521 to generate and output the latch pulse 522 to the source drivers SD4-SD6. The latch pulse 522 thus falls behind the latch pulse 521. Detailed descriptions of the delay apparatus 503 is shown in the following.

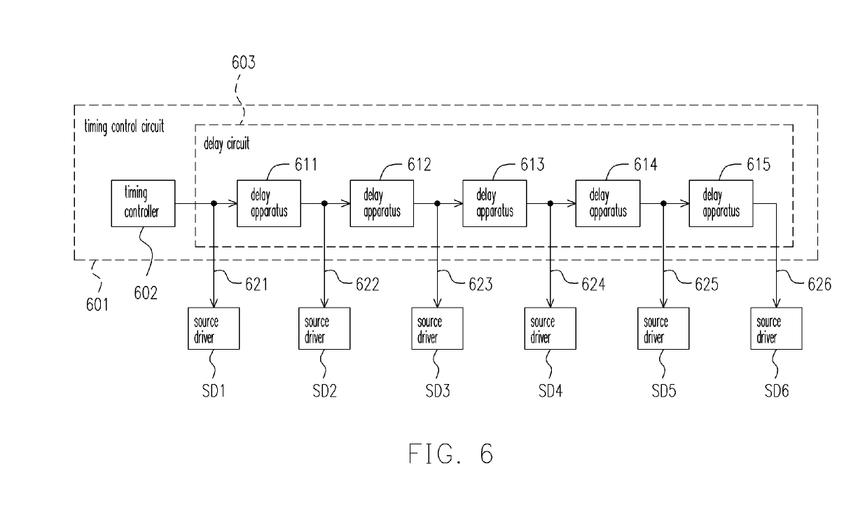

FIG. 6 is a schematic drawing showing a timing control circuit according to another embodiment of the present invention. Referring to FIG. 6, except for the first latch pulse 621, each of the latch pulses 622-626 are generated by delaying the last latch pulses 621-625 corresponding thereto. The timing control circuit 601 comprises the timing controller 602 and the delay circuit 603. The timing controller 602 provides the first latch pulse control signal 621. According to the first latch pulse 621, the delay circuit 603 generates and outputs the latch pulses 622-626.

The delay circuit 603 comprises five delay apparatuses 611-615. Wherein, the first delay apparatus 611 is coupled to the timing controller 602, and the other delay apparatuses 612-615 are coupled to the previous delay apparatuses 611-614 corresponding thereto, respectively. The delay apparatuses 611-615 receive and delay the latch pulses 621-625 to generate and output the latch pulses 622-626, respectively. In addition to the embodiment in FIG. 6, the present invention also comprises modifications of the timing control circuit 601. That is, the number of the delay apparatuses and the latch pulses can be any positive integer larger than 1, as long as the number of the delay apparatuses is the number of the latch pulses minus 1.

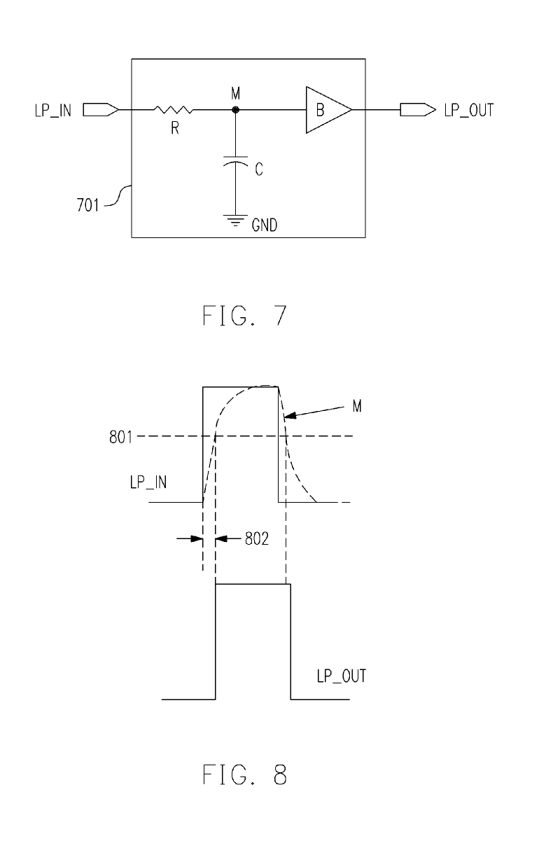

FIG. 7 is a schematic drawing showing a delay apparatus in a timing control circuit according to an embodiment of the present invention. Referring to FIG. 7, the delay apparatus 701 comprises a resistor R, a capacitor C, and a buffer B. Wherein, the resistor R is coupled to the input terminal LP_IN of the delay apparatus 701. The capacitor C is coupled between the resistor R and the ground line GND. The buffer B is coupled among the resistor R, the capacitor C, and the output terminal LP_OUT of the delay apparatus 701. The buffer B receives the signal from the connection point M of the resistor R and the capacitor C, processes the signal into a square wave, and outputs the square wave. Details can be referred in FIG. 8.

FIG. 8 is a drawing showing a signal sequence of the delay apparatus shown in FIG. 7. Referring to FIG. 8, the square wave LP_IN represents the input signal of the delay apparatus 701. Due to the operation of the resistor R and the capacitor C, the signal at the connection point M in FIG. 7 is similar to the signal M shown in FIG. 8. The signal M flows through the buffer B, and becomes the square wave LP_OUT shown in FIG. 8.

In this embodiment, the buffer B comprises two inverters connected in series. The horizontal dotted line 801 shown in FIG. 8 is the differentiating voltage of logic-high and logic-low voltages of the inverters. Accordingly, after two inversions by the buffer B, the signal M shown in FIG. 8 becomes the signal LP_OUT. The operations of the resistor R, the capacitor C and the buffer B result in a delay time 802 between the signals LP_OUT and LP_IN. The length of the delay time 802 is the resistance of the resistor R multiplying the capacitance of the capacitor C.

The buffer B of the present invention is not limited to two inverters connected in series. In other embodiments, other circuits with the same function may be used. The delay apparatus of the present invention is not limited to the delay apparatus 701 shown in FIG. 7. In other embodiments, any circuits with the same function as the delay apparatus 701 may be used.

In addition to the timing control circuit described above, the present invention also comprises a timing control method corresponding thereto. After reading the circuit embodiments described above, one of ordinary skill in the art can easily understand the timing controlling method of the present invention. Detailed descriptions are not repeated.

According to the embodiments described above, signal delays are provided to the latch pulses from different source drivers. In cooperation with the transmission delay of the gate pulse, the area with obvious gate pulse delays can receive the corresponding pixel signals in a later order. With the cooperation of the delays of the gate pulse and the pixel signal, rewriting can be effectively prevented. Unlike the conventional technology in which pixels are turned off in advance, the present invention increases pixel charging time to reduce the size of the thin film transistors and increase aperture ratio. In addition, because source drivers have different output timing, electrical field interference can thus be reduced.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A timing control circuit for outputting a plurality of latch pulses, the timing control circuit characterized in that:
among the latch pulses, except the first latch pulse, each latch pulse synchronizes with or follows behind a previous latch pulse corresponding thereto, and at least one latch pulse falls behind a previous latch pulse corresponding thereto.

2. The timing control circuit of claim 1, wherein there are two latch pulses, and the second latch pulse is behind the first latch pulse.

3. The timing control circuit of claim 2, further comprising:
a timing controller, outputting the first latch pulse; and
a delay apparatus, receiving and delaying the first latch pulse to generate and output the second latch pulse.

4. The timing control circuit of claim 3, wherein the delay apparatus further comprises:
a resistor coupled to an input terminal of the delay apparatus;
a capacitor coupled between the resistor and a ground line; and
a buffer coupled among the resistor, the capacitor and an output terminal of the delay apparatus, receiving a signal from a connection point of the resistor and the capacitor, processing the signal into a square wave and outputting the square wave.

5. The timing control circuit of claim 4, wherein the buffer comprises two inverters connected in series.

6. The timing control circuit of claim 1, wherein except for the first latch pulse, each latch pulse follows behind the previous latch pulse corresponding thereto.

7. The timing control circuit of claim 6, further comprising:
a timing controller outputting the first latch pulse; and
a delay circuit, according to the first latch pulse, generating and outputting the other latch pulses.

8. The timing control circuit of claim 7, wherein the delay circuit further comprises:
a plurality of delay apparatuses, the number of the delay apparatus being the number of the latch pulses minus 1, wherein the first delay apparatus is coupled to the timing controller, the I-th delay apparatus is coupled to the (I−1)-th delay apparatus, the I-th delay apparatus receives and delays the Ith latch pulse to generate and output the (I+1)-th latch pulse, wherein I is a positive integer, 1≦I≦N−1, and N is the amount of the latch pulses.

9. The timing control circuit of claim 8, wherein each delay apparatus further comprises:
a resistor coupled to an input terminal of the delay apparatus;
a capacitor coupled between the resistor and a ground line; and
a buffer coupled among the resistor, the capacitor and an output terminal of the delay apparatus, receiving a signal from a connection point of the resistor and the capacitor, processing the signal into a square wave and outputting the square wave.

10. The timing control circuit of claim 9, wherein the buffer comprises two inverters connected in series.

11. A timing control method for providing a plurality of latch pulses, the timing control method characterized in that:
among the latch pulses, except for the first latch pulse, each latch pulse synchronizes with or follows behind a previous latch pulse corresponding thereto, and at least one latch pulse falls behind a previous latch pulse corresponding thereto.

12. The timing control method of claim 11, wherein there are two latch pulses, and the second latch pulse is behind the first latch pulse.

13. The timing control method of claim 11, wherein except for the first latch pulse, each latch pulse follows behind the previous latch pulse corresponding thereto.
